(19) United States
(12) Patent Application Publication
(10) Pub. No.: US 2023/0314503 A1
(43) Pub. Date: Oct. 5, 2023

(54) TECHNOLOGIES FOR TESTING LIQUID METAL ARRAY INTERCONNECT PACKAGES

(71) Applicant: Intel Corporation, Santa Clara, CA (US)

(72) Inventors: Gregorio Roberto Murtagian, Phoenix, AZ (US); Karumbu Nathan Meyyappan, Portland, OR (US)

(73) Assignee: Intel Corporation, Santa Clara, CA (US)

(21) Appl. No.: 17/709,630

(22) Filed: Mar. 31, 2022

(51) Int. Cl. G01R 31/28; G01R 1/04

(52) U.S. Cl. CPC G01R 31/2889; G01R 31/2853; G01R 1/0483; G01R 31/2896; H01L 27/0886

(57) ABSTRACT

Technologies for testing integrated circuit components with liquid metal interconnects are disclosed. In the illustrative embodiment, a bed of nails adapter can mate with an integrated circuit component with liquid metal interconnects. The nails pierce a sealing cap layer that seals the liquid metal interconnects, electrically coupling the nails to the liquid metal interconnects. An underside of the bed of nails adapter has an array of pads that are coupled to the nails. The array of pads may be used to mate the bed of nails adapter and integrated circuit component with several land grid array sockets for testing of the integrated circuit component. As the bed of nails adapter does not need to be removed as the integrated circuit component is moved to a new land grid array socket, the number of times the sealing cap layer is pierced by nails during testing is reduced.

### BACKGROUND

Circuit boards may be manufactured with contact pads for mating with integrated circuit components, such as a processor. For example, a socket may be mated with a circuit board, and a processor can then mate with the socket. In some cases, the socket may be soldered to the circuit board. In other cases, the socket may be compression mounted to contact pads on the circuit board. A socket connected by solder may induce stress to the circuit board, cause warpage, or risk a solder joint failing. Compression mounting may require a large amount of force, particularly for high-pin count integrated circuit components.

### BRIEF DESCRIPTION OF THE DRAWINGS

FIG. 1 is an isometric view of an integrated circuit component, a bed of nails adapter, and a land grid array (LGA) socket separated from each other.

FIG. 2 is an isometric view of a bottom side of the integrated circuit component of FIG. 1.

FIG. 3 is a cross-section view of the integrated circuit component, the bed of nails adapter, and the LGA socket of FIG. 1.

FIG. 4 is an isometric view of an integrated circuit component mated with a bed of nails adapter.

FIG. 5 is a cross-section view of the integrated circuit component and the bed of nails adapter of FIG. 4.

FIG. 6 is an isometric view of an integrated circuit component, a bed of nails adapter, and an LGA socket mated together.

FIG. 7 is a cross-section view of the integrated circuit component, the bed of nails adapter, and the LGA socket of FIG. 6.

FIG. 8 is a flowchart of one embodiment of a method of testing an integrated circuit component using a bed of nails adapter.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

In various embodiments disclosed herein, an integrated circuit component may have a liquid metal interconnect array. The liquid metal interconnect array may be sealed by a sealing cap layer. In use, a bed of nails socket on a circuit board can interface with the liquid metal interconnect array by piercing the sealing cap layer with a nail. The liquid metal interconnect array can make a good electrical connection with the nail without the stress of a soldered socket and without the compression of a land grid array. Repeated piercing of the sealing cap layer may damage it, causing the liquid metal to leak out with a resulting failure as an interconnect. In a typical use, an integrated circuit component may mate with a bed of nails socket once or a handful of times over the lifetime of the integrated circuit component. However, an integrated circuit component may be connected to a circuit board dozens of times during testing, possibly leading to failure of the liquid metal interconnect array.

In order to reduce the number of times a bed of nails socket pierces the sealing cap layer, in the illustrative embodiment, a bed of nails adapter includes a bed of nails array on one side and a land grid array on the opposite side. In use, the bed of nails adapter can mate with the integrated circuit component using the bed of nails array. The land grid array of the bed of nails adapter can mate with an LGA socket of one or more test interface units. The bed of nails adapter can remain mated with the integrated circuit component as it is moved to various test interface units without repeatedly piercing the sealing cap layer. When testing is complete, the bed of nails adapter can be removed from the integrated circuit component.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

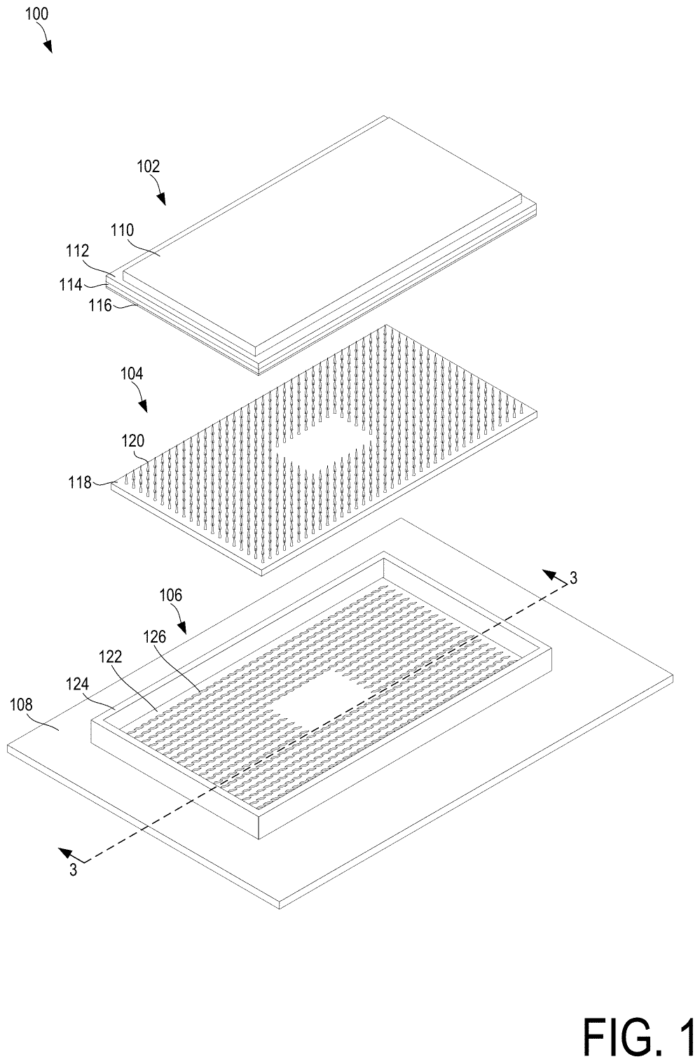

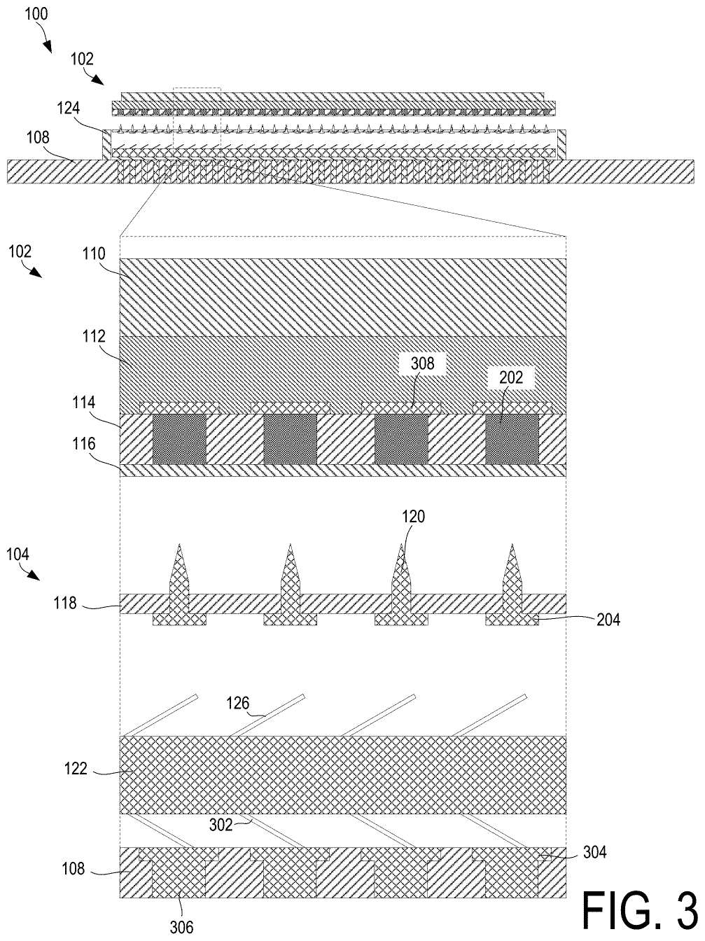

Referring now to FIG. 1, in one embodiment, a system 100 includes an integrated circuit component 102, a bed of nails adapter 104, and an LGA socket 106 on a circuit board 108. A cross-sectional view of the system 100 is shown in FIG. 3.

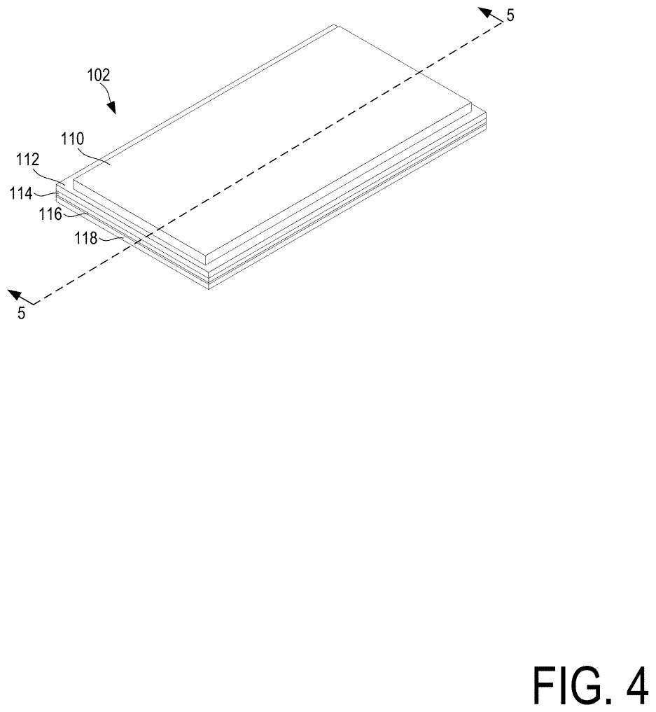

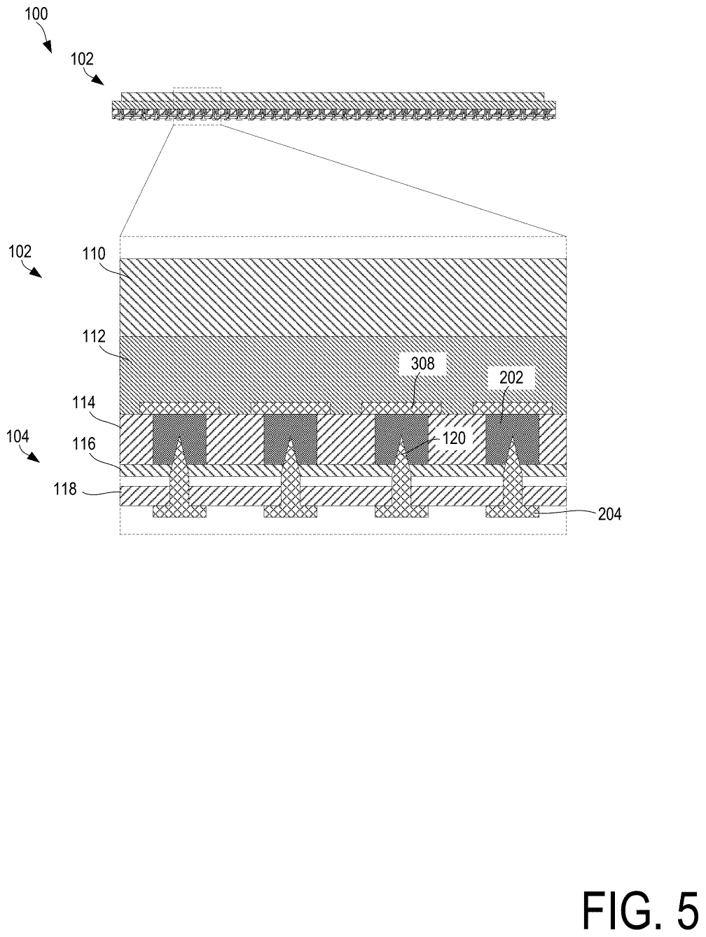

In use, the bed of nails adapter 104 can mate with the integrated circuit component 102, as shown in FIG. 4. A cross-sectional view of the bed of nails adapter 104 mated with the integrated circuit component 102 is shown in FIG. 5. The nails 120 pierce the sealing cap layer 116 and become electrically coupled to the liquid metal interconnects 202. The bed of nails adapter 104 may be secured to the integrated circuit component 102 with one or more fasteners, such as a clip, a spring screw, screws, bolts, etc.

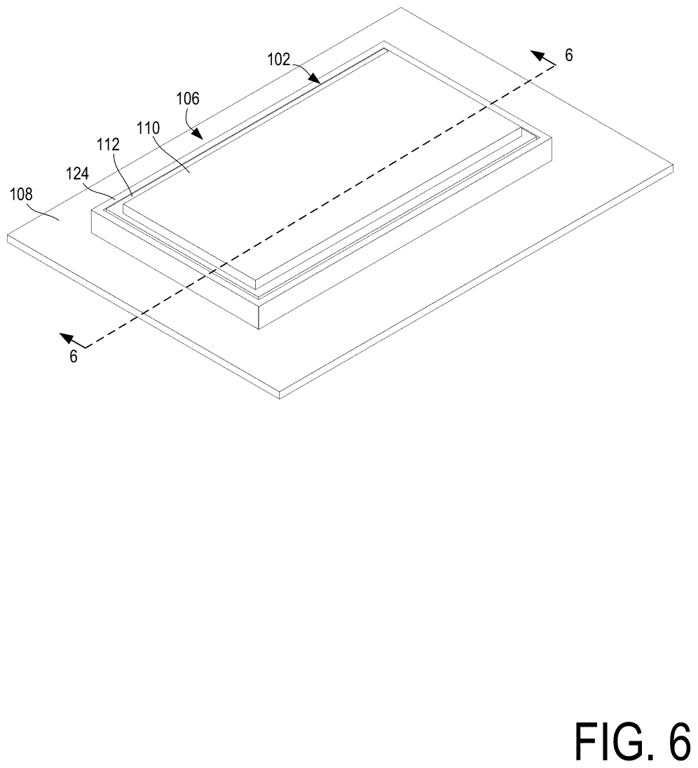

With the bed of nails adapter 104 connected to it, the integrated circuit component 102 can be connected to several test interface units without repeated piercing of the sealing cap layer 116. For example, the integrated circuit component 102 and the bed of nails adapter 104 can mate with an LGA socket 106, as shown in FIG. 5. FIG. 6 shows a cross-section view of the integrated circuit component 102, the bed of nails adapter 104, and the LGA socket 106 of a test interface unit. The integrated circuit component 102 may be secured in place with one or more fasteners, such as a clip, a spring screw, screws, bolts, land grid array (LGA) loading mechanism, etc. In some embodiments, a heat sink may be held in by one or more such fasteners, which may transfer a force to the integrated circuit component 102 towards the LGA socket 106.

The integrated circuit component 102 and the bed of nails adapter 104 can be removed from the LGA socket 106 without removing the bed of nails adapter 104 from the integrated circuit component 102. The integrated circuit component 102 and the bed of nails adapter 104 can then be mated with another LGA socket 106 for further testing.

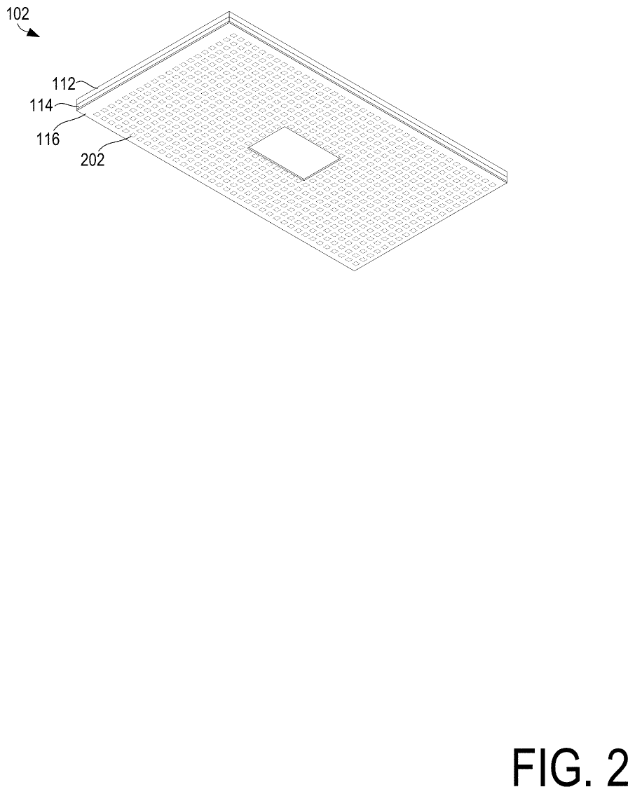

The illustrative integrated circuit component 102 includes an integrated heat spreader on a circuit board 112. An isometric view of the integrated circuit component 102 showing the bottom surface of the integrated circuit component is shown in FIG. 2. An interposer 114 is adjacent the bottom side of the circuit board 112. It should be appreciated that, as used herein, the “top side,” “bottom side,” etc., is an arbitrary designation used for clarity and does not denote a particular required orientation for manufacture or use. The interposer 114 includes an array of liquid metal interconnects 202. The interposer 114 may be any suitable material, such as a dielectric. A sealing cap layer 116 seals the liquid metal interconnects 202, preventing them from leaking out. Each liquid metal interconnect is adjacent a contact pad 308 of the circuit board 112. Each contact pad 308 may be connected to a trace, via, or other interconnect on the circuit board 112. Each contact pad 308 may connect to a die or other component mounted on the circuit board 112.

Each liquid metal interconnect 202 may have any suitable dimensions, such as a width, length, and/or thickness of 0.1-2 millimeters. The liquid metal interconnects 202 may have any suitable pitch, such as 0.2-2.5 millimeters. The integrated circuit component 102 may include any suitable number of liquid metal interconnects 202, such as 100-20,000 liquid metal interconnects 202. Each liquid metal interconnect 202 may have any suitable shape, such as a cylinder, cuboid, parallelepiped, etc. The array of liquid metal interconnects 202 may have one or more areas where no or fewer liquid metal interconnects 202 are present, such as an interior rectangular area with no liquid metal interconnects 202. The circuit board 112 may have components in the areas where no or fewer liquid metal interconnects 202 are present (not shown in FIG. 2). The array of liquid metal interconnects 202 may have any suitable width or length, such as 5-250 millimeters.

Each contact pad 308 of the circuit board 112 may have a similar size and pitch as the liquid metal interconnects 202, although the thickness may be less. The contact pads 308 may be any suitable material, such as copper, aluminum, or other conductor.

Each liquid metal interconnect 202 may be made of any suitable liquid metal. In the illustrative embodiment, the liquid metal interconnect 202 includes gallium. For example, the liquid metal interconnect 202 may be embodied as gallium, a gallium/indium alloy, a gallium/tin alloy, etc. In some embodiments, the liquid metal interconnect 202 may be embodied as a low-temperature solder. As used herein, low-temperature solder refers to solder with a melting point less than 180° Celsius.

The sealing cap layer 116 may be any suitable material, such as a foam or polymer. In the illustrative embodiment, after being pierced by a nail 120 of the bed of nails adapter 104, the sealing cap layer 116 partially or fully seals the liquid metal interconnects 202, preventing most or all of the liquid metal interconnect 202 from leaking out. The sealing cap layer 116 may be any suitable thickness, such as 0.1-1 millimeter. In the illustrative embodiment, the sealing cap layer 116 has a thickness of about 0.3 millimeters.

The integrated circuit component 102 may include one or more dies, chips, or other components connected to the circuit board 112. The integrated circuit component 102 may be or otherwise include, e.g., a processor, a memory, an accelerator device, etc.

The bed of nails adapter 104 includes a carrier 118, a plurality of nails 120, and a plurality of pads 204. The carrier 118 may be any suitable material, such as metal, plastic, fiberglass and resin such as FR-4, etc. In the illustrative embodiment, each pad 204 is the head of a corresponding nail 120. In other embodiments, there may be a separate interconnect through the carrier 118 connecting each pad 204 to a corresponding nail 120. The plurality of nails 120 and/or the plurality of pads 204 may be made of any suitable material, such as copper, aluminum, or other conductor. In some embodiments, the pads 204 may be coated with, e.g., gold. The nails 120 may have any suitable dimensions, such as a width of 0.1-1 millimeter and a length of 0.2-3 millimeters. The tip of the nails 120 may have any suitable radius of curvature, such as 0.01-10 micrometers. The tip of the nails 120 may have any suitable bevel angle, such as 10-30°. The pads 204 may have similar dimensions to the pads 308.

The LGA socket 106 includes a carrier 122, a frame 124, and an array of pins 126. The carrier 122 may be any suitable material, such as metal, plastic, fiberglass and resin such as FR-4. The frame 124 may be made from any suitable material that can hold the carrier 122 in place, such as plastic, metal, etc. Each pin 126 is configured to contact a corresponding pad on the integrated circuit component 102. The LGA socket 106 also includes pins 302 on the opposite side. Each pin 302 is configured to contact a corresponding contact pad 304 of the circuit board 108.

In the illustrative embodiment, the circuit board 108 is made from fiberglass and resin, such as FR-4. In other embodiments, other types of circuit board 108 may be used. The illustrative circuit board 108 may have any suitable length or width, such as 10-500 millimeters. The circuit board 108 may have any suitable thickness, such as 0.2-5 millimeters. The circuit board 108 includes an array of landing pads 304. In the illustrative embodiment, each landing pad 304 is made of copper. In other embodiments, other materials such as aluminum may be used and/or the landing pad 304 may be coated with another material, such as tin or nickel. Each landing pad 304 may have similar dimensions as the pads 308. In some embodiments, the array of pins 302 may interface with pads on an integrated circuit component instead of an FR-4 circuit board, such as a die, chip, system-on-a-chip, etc.

In the illustrative embodiment, each landing pad 304 is connected to or forms part of a via 306 that connects the landing pad 304 to one or more other components or traces. Additionally or alternatively, in some embodiments, some or all of the landing pads 304 may be connected to a trace on an outer surface of the circuit board 108.

The circuit board 108 may have mounted on it additional components not shown, such as capacitors, resistors, integrated circuit components, power components, interconnects, etc. In the illustrative embodiment, the circuit board 108 and other components mounted on the circuit board form a test interface unit that can perform one or more tests on the integrated circuit component 102 to, e.g., test connections or functionality of the integrated circuit component 102.

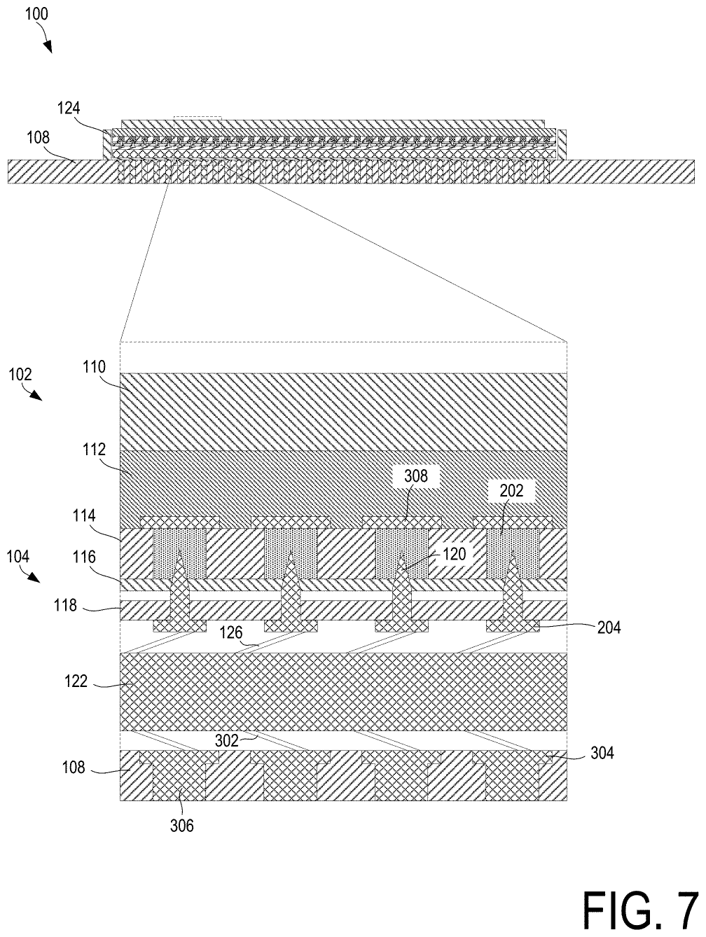

Referring now to FIGS. 6 and 7, the integrated circuit component 102 is mated with the bed-of-nails adapter 104 and the LGA socket 106. In the illustrative embodiment, the integrated circuit component 102 and the bed-of-nails adapter 104 are pressed into the LGA socket 106, such as by a heat sink or other retaining mechanism. The pressure on the integrated circuit component 102 and the bed-of-nails adapter 104 flexes the pins 126, 302, ensuring good electrical contact between each pin 126, 302 and the corresponding contact pad 204, 304.

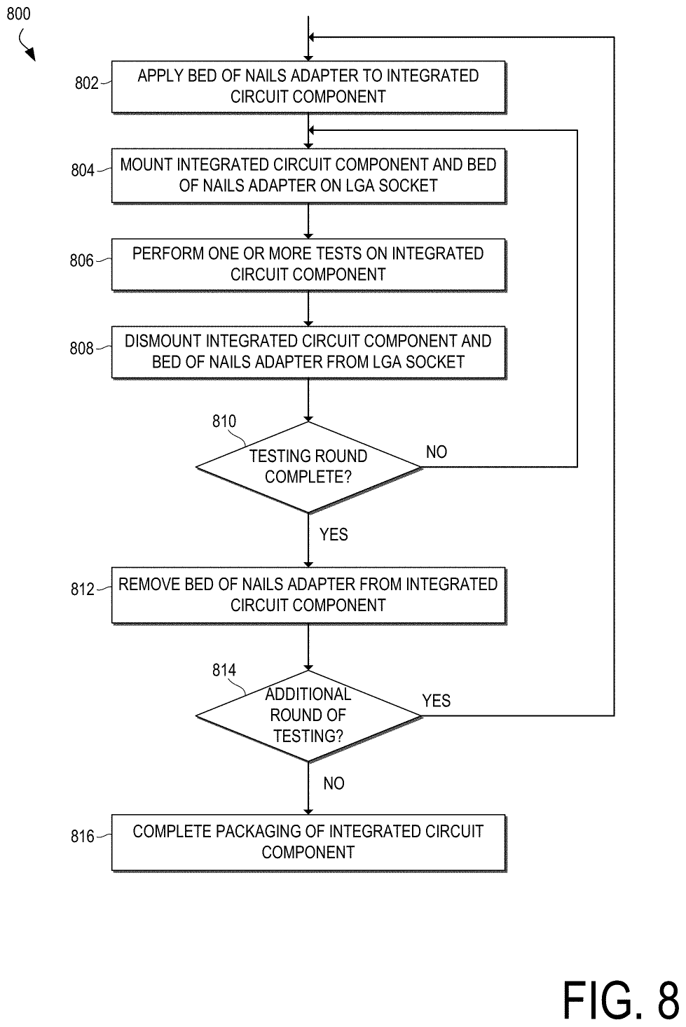

Referring now to FIG. 8, a flowchart for a method 800 for using the bed of nails adapter 104 is shown. The method 800 may be executed by a technician and/or by one or more automated machines. In some embodiments, one or more machines may be programmed to do some or all of the steps of the method 800. Such a machine may include, e.g., a memory, a processor, data storage, etc. The memory and/or data storage may store instructions that, when executed by the machine, causes the machine to perform some or all of the steps of the method 800.

The method 800 begins in block 802, in which a bed of nails adapter 104 is applied to an integrated circuit component 102. The bed of nails adapter 104 may be secured to the integrated circuit component 102 with one or more fasteners, such as a clip, a spring screw, screws, bolts, etc.

In block 804, the integrated circuit component 102 and bed of nails adapter 104 is mounted on an LGA socket 106 of a testing interface unit. In some embodiments, the integrated circuit component 102 and bed of nails adapter 104 may interface with a testing interface unit by an interface other than an LGA socket 106. In block 806, the testing interface unit performs one or more tests on the integrated circuit component 102, such as by testing one or more connections or functionality of the integrated circuit component 102.

In block 808, the integrated circuit component 102 and the bed of nails adapter 104 is removed from the LGA socket 106.

In block 810, if the round of testing is not complete, the method 800 loops back to block 804 to mount the integrated circuit component 102 and the bed of nails adapter 104 on an LGA socket 106. The LGA socket 106 may be the same as the previous one or may be a different one. It should be appreciated that, when connecting and disconnecting the integrated circuit component 102 and the bed of nails adapter 104 from LGA sockets 106, the nails 120 do not repeatedly pierce the sealing cap layer 116. The integrated circuit component 102 may be connected to any suitable number of LGA sockets 106 during a round of testing, such as 1-10.

If the round of testing is complete, the method 800 proceeds to block 812, in which the bed of nails adapter 104 is removed from the integrated circuit component 102. In the illustrative embodiment, the integrated circuit component 102 may be stored in between rounds of testing.

In block 814, if there is an additional round of testing, the method 800 loops back to block 802 to apply a bed of nails adapter 104 to the integrated circuit component 102. In the illustrative embodiment, the bed of nails adapter 104 is removed between rounds of testing. In other embodiments, the bed of nails adapter 104 may remain mated with the integrated circuit component 102 between some or all of the rounds of testing. The integrated circuit component 102 may undergo any suitable number of rounds of testing, such as 1-10.

Referring back to block 814, if there are not additional rounds of testing, then the packaging of the integrated circuit component 102 in, e.g., plastic or cardboard, can be completed.

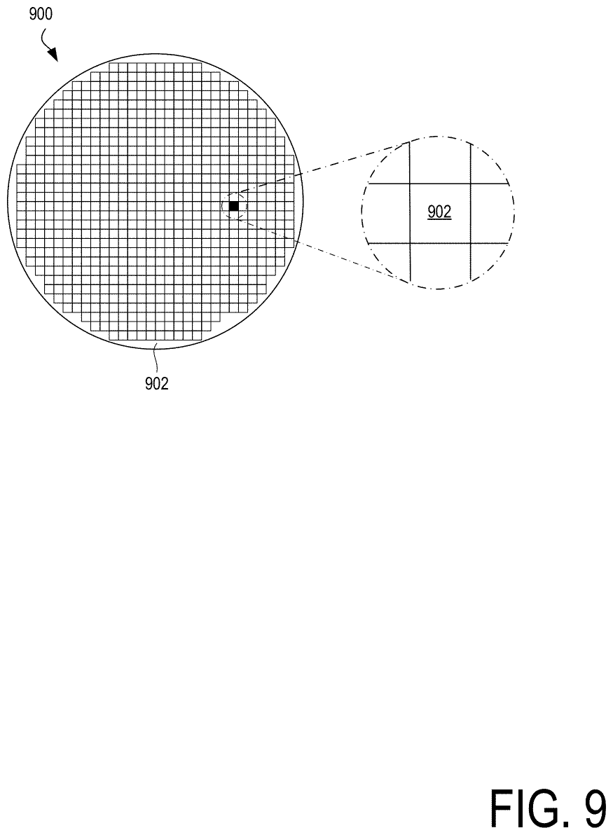

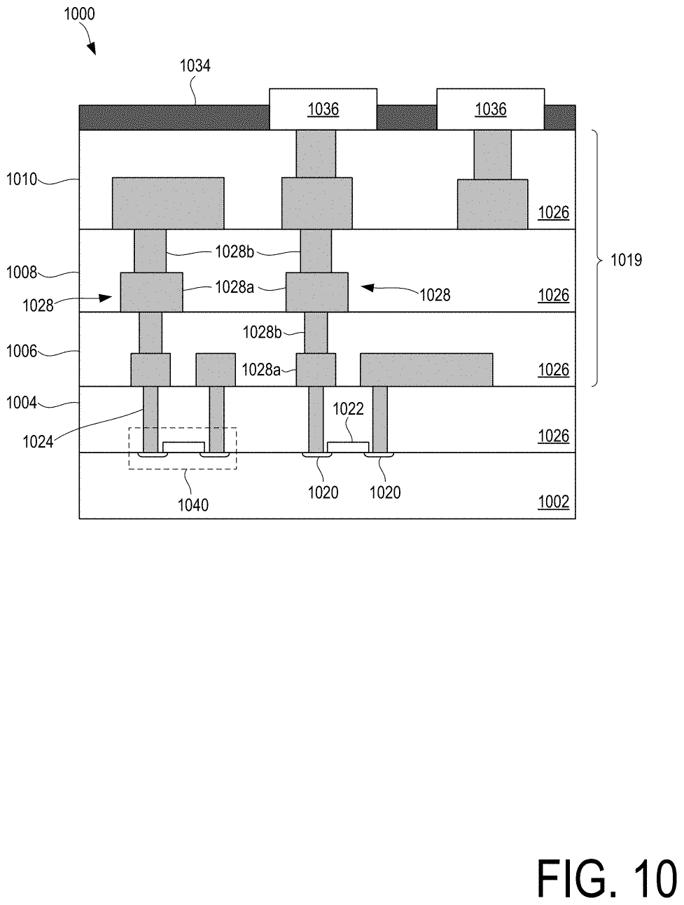

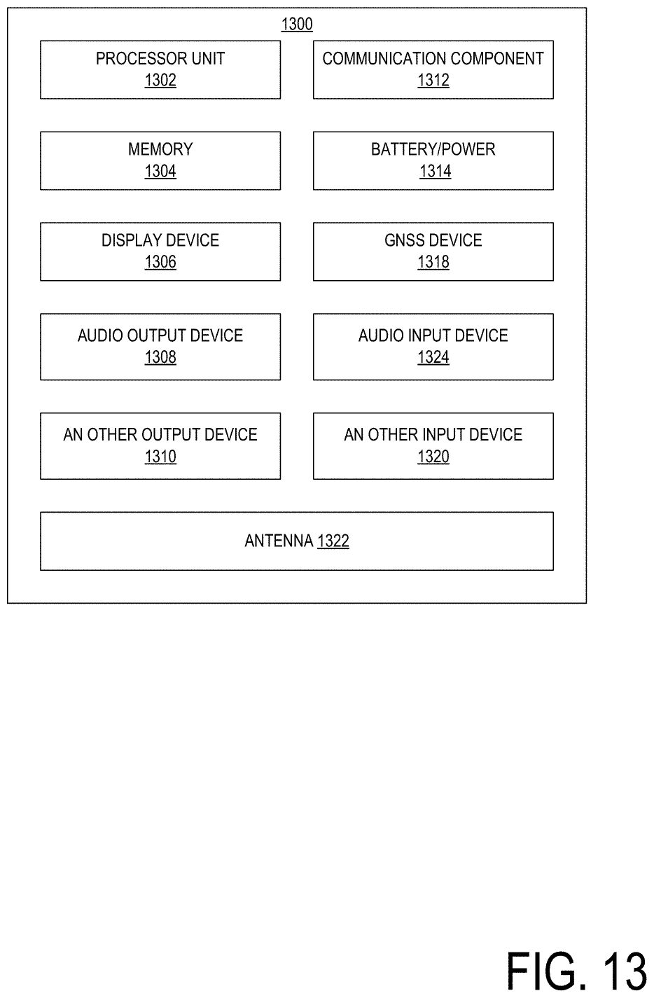

FIG. 9 is a top view of a wafer 900 and dies 902 that may be included in any of the integrated circuit components 102 disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array. Various ones of the integrated circuit components 102 disclosed herein may be manufactured using a die-to-wafer assembly technique in which some dies are attached to a wafer 900 that include others of the dies, and the wafer 900 is subsequently singulated.

FIG. 10 is a cross-sectional side view of an integrated circuit device 1000 that may be included in any of the integrated circuit components 102 disclosed herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

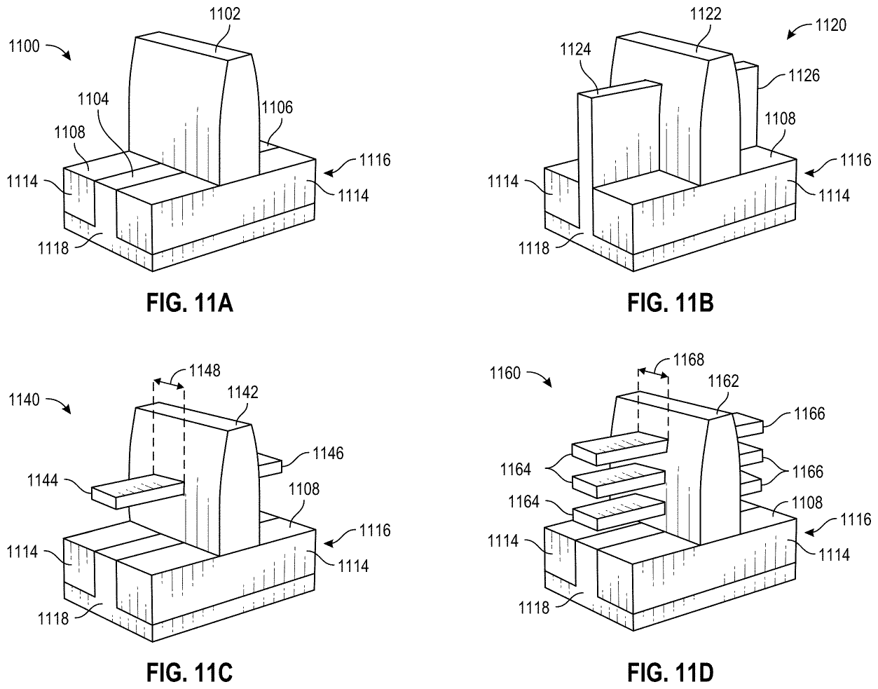

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components. The conductive contacts 1036 may serve as the conductive contacts 308, as appropriate.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036. These additional conductive contacts may serve as the conductive contacts 308, as appropriate.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. These additional conductive contacts may serve as the conductive contacts 308. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

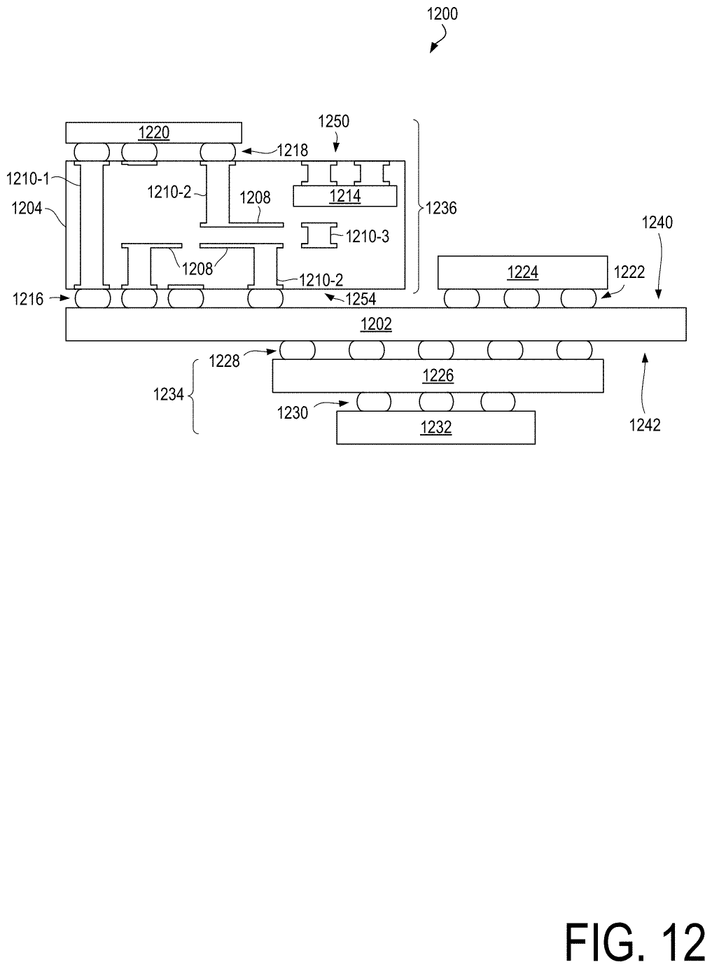

FIG. 12 is a cross-sectional side view of an integrated circuit device assembly 1200 that may include any of the integrated circuit components 102 disclosed herein. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the integrated circuit components 102 disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. In some embodiments the circuit board 1202 may be, for example, the circuit board 112. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1216 may serve as the coupling components illustrated or described for any of the substrate assembly or substrate assembly components described herein, as appropriate.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art. In embodiments where the interposer is a non-printed circuit board

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the integrated circuit components 102 disclosed herein. For example, any suitable ones of the components of the electrical device 1300 may include one or more of the integrated circuit device assemblies 1200, integrated circuit components 1220, integrated circuit devices 1000, or integrated circuit dies 902 disclosed herein, and may be arranged in any of the integrated circuit components 102 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

### EXAMPLES

Illustrative examples of the technologies disclosed herein are provided below. An embodiment of the technologies may include any one or more, and any combination of, the examples described below.

Example 1 includes a system comprising an integrated circuit component, the integrated circuit component comprising a plurality of contact pads; an interposer comprising a plurality of liquid metal interconnects, wherein individual liquid metal interconnects of the plurality of liquid metal interconnects are adjacent an contact pad of the plurality of contact pads; and a cap layer that seals the plurality of liquid metal interconnects, and an adapter comprising a carrier comprising a top surface and a bottom surface; a plurality of nails, wherein individual nails of the plurality of nails extend from the top surface, pierce the cap layer, and are electrically coupled to one of the plurality of liquid metal interconnects; and a plurality of pads on the bottom surface, wherein individual pads of the plurality of pads are electrically coupled to one of the plurality of nails.

Example 2 includes the subject matter of Example 1, and further including a test interface unit to test the integrated circuit component; and a compressible socket mated with the test interface unit and the adapter, the compressible socket comprising a plurality of pins, wherein individual pins of the plurality of pins are in contact with one of the plurality of pads.

Example 3 includes the subject matter of any of Examples 1 and 2, and wherein the test interface unit comprises a plurality of pads, wherein the compressible socket comprises a second plurality of pins, wherein individual pins of the second plurality of pins are in contact with one of the plurality of pads of the test interface unit.

Example 4 includes the subject matter of any of Examples 1-3, and wherein individual liquid metal interconnects of the plurality of liquid metal interconnects comprise gallium.

Example 5 includes the subject matter of any of Examples 1-4, and wherein individual liquid metal interconnects of the plurality of liquid metal interconnects comprise gallium and indium.

Example 6 includes the subject matter of any of Examples 1-5, and wherein individual liquid metal interconnects of the plurality of liquid metal interconnects comprise gallium and tin.

Example 7 includes the subject matter of any of Examples 1-6, and wherein individual liquid metal interconnects of the plurality of liquid metal interconnects comprise a low-temperature solder.

Example 8 includes the subject matter of any of Examples 1-7, and wherein the plurality of liquid metal interconnects comprises at least 1,000 liquid metal interconnects.

Example 9 includes the subject matter of any of Examples 1-8, and wherein the integrated circuit component is a processor.

Example 10 includes an adapter comprising a carrier comprising a top surface and a bottom surface; a plurality of nails, wherein individual nails of the plurality of nails extend from the top surface, wherein the plurality of nails are to interface with an array; and a plurality of pads on the bottom surface, wherein individual pads of the plurality of pads are electrically coupled to one of the plurality of nails, wherein the plurality of pads are to interface with a land grid array socket.

Example 11 includes the subject matter of Example 10, and wherein the plurality of nails comprises at least 1,000 nails.

Example 12 includes a system comprising the adapter of Example 10, the system further comprising an integrated circuit component, the integrated circuit component comprising a plurality of contact pads; an interposer comprising a plurality of liquid metal interconnects, wherein individual liquid metal interconnects of the plurality of liquid metal interconnects are adjacent an contact pad of the plurality of contact pads; and a cap layer that seals the plurality of liquid metal interconnects, wherein individual nails of the plurality of nails pierce the cap layer and are electrically coupled to one of the plurality of liquid metal interconnects.

Example 13 includes the subject matter of Example 12, and further including a test interface unit to test the integrated circuit component; and a compressible socket mated with the test interface unit and the adapter, the compressible socket comprising a plurality of pins, wherein individual pins of the plurality of pins are in contact with one of the plurality of pads.

Example 14 includes the subject matter of any of Examples 12 and 13, and wherein the test interface unit comprises a plurality of pads, wherein the compressible socket comprises a second plurality of pins, wherein individual pins of the second plurality of pins are in contact with one of the plurality of pads of the test interface unit.

Example 15 includes the subject matter of any of Examples 12-14, and wherein individual liquid metal interconnects of the plurality of liquid metal interconnects comprise gallium.

Example 16 includes the subject matter of any of Examples 12-15, and wherein individual liquid metal interconnects of the plurality of liquid metal interconnects comprise gallium and indium.

Example 17 includes the subject matter of any of Examples 12-16, and wherein individual liquid metal interconnects of the plurality of liquid metal interconnects comprise gallium and tin.

Example 18 includes the subject matter of any of Examples 12-17, and wherein individual liquid metal interconnects of the plurality of liquid metal interconnects comprise a low-temperature solder.

Example 19 includes the subject matter of any of Examples 12-18, and wherein the plurality of liquid metal interconnects comprises at least 1,000 liquid metal interconnects.

Example 20 includes the subject matter of any of Examples 12-19, and wherein the integrated circuit component is a processor.

Example 21 includes a method comprising mating an adapter with an integrated circuit component, wherein the adapter comprises a plurality of nails and a plurality of pads, wherein individual pads of the plurality of pads are electrically coupled to one of the plurality of nails, wherein the integrated circuit component comprises a plurality of liquid metal interconnects and a cap layer that seals the plurality of liquid metal interconnects, wherein mating the adapter to the integrated circuit component comprises piercing the cap layer with individual nails of the plurality of nails; mating the adapter and the integrated circuit component with a testing interface unit; and performing one or more tests on the integrated circuit component by the testing interface unit.

Example 22 includes the subject matter of Example 21, and wherein mating the adapter and the integrated circuit component with the testing interface unit comprises mating the adapter with a land grid array socket of the testing interface unit.

Example 23 includes the subject matter of any of Examples 21 and 22, and further including, without removing the adapter from the integrated circuit component removing the adapter and the integrated circuit component from the testing interface unit; mating the adapter and the integrated circuit component with a second testing interface unit different from the testing interface unit; and performing one or more tests on the integrated circuit component by the second testing interface unit.

Example 24 includes the subject matter of any of Examples 21-23, and wherein individual liquid metal interconnects of the plurality of liquid metal interconnects comprise gallium.

Example 25 includes the subject matter of any of Examples 21-24, and wherein individual liquid metal interconnects of the plurality of liquid metal interconnects comprise gallium and indium.

Example 26 includes the subject matter of any of Examples 21-25, and wherein individual liquid metal interconnects of the plurality of liquid metal interconnects comprise gallium and tin.

Example 27 includes the subject matter of any of Examples 21-26, and wherein individual liquid metal interconnects of the plurality of liquid metal interconnects comprise a low-temperature solder.

Example 28 includes the subject matter of any of Examples 21-27, and wherein the plurality of liquid metal interconnects comprises at least 1,000 liquid metal interconnects.

Example 29 includes the subject matter of any of Examples 21-28, and wherein the integrated circuit component is a processor.

1. A system comprising:
an integrated circuit component, the integrated circuit component comprising:
a plurality of contact pads;
an interposer comprising a plurality of liquid metal interconnects, wherein individual liquid metal interconnects of the plurality of liquid metal interconnects are adjacent an contact pad of the plurality of contact pads; and
a cap layer that seals the plurality of liquid metal interconnects, and
an adapter comprising:
a carrier comprising a top surface and a bottom surface;
a plurality of nails, wherein individual nails of the plurality of nails extend from the top surface, pierce the cap layer, and are electrically coupled to one of the plurality of liquid metal interconnects; and
a plurality of pads on the bottom surface, wherein individual pads of the plurality of pads are electrically coupled to one of the plurality of nails.

2. The system of claim 1, further comprising:
a test interface unit to test the integrated circuit component; and
a compressible socket mated with the test interface unit and the adapter, the compressible socket comprising a plurality of pins, wherein individual pins of the plurality of pins are in contact with one of the plurality of pads.

3. The system of claim 2, wherein the test interface unit comprises a plurality of pads, wherein the compressible socket comprises a second plurality of pins, wherein individual pins of the second plurality of pins are in contact with one of the plurality of pads of the test interface unit.

4. The system of claim 1, wherein individual liquid metal interconnects of the plurality of liquid metal interconnects comprise gallium.

5. The system of claim 1, wherein individual liquid metal interconnects of the plurality of liquid metal interconnects comprise gallium and indium.

6. The system of claim 1, wherein individual liquid metal interconnects of the plurality of liquid metal interconnects comprise gallium and tin.

7. The system of claim 1, wherein individual liquid metal interconnects of the plurality of liquid metal interconnects comprise a low-temperature solder.

8. The system of claim 1, wherein the plurality of liquid metal interconnects comprises at least 1,000 liquid metal interconnects.

9. The system of claim 1, wherein the integrated circuit component is a processor.

10. An adapter comprising:
a carrier comprising a top surface and a bottom surface;
a plurality of nails, wherein individual nails of the plurality of nails extend from the top surface, wherein the plurality of nails are to interface with an array; and
a plurality of pads on the bottom surface, wherein individual pads of the plurality of pads are electrically coupled to one of the plurality of nails, wherein the plurality of pads are to interface with a land grid array socket.

11. The adapter of claim 10, wherein the plurality of nails comprises at least 1,000 nails.

12. A system comprising the adapter of claim 10, the system further comprising:
an integrated circuit component, the integrated circuit component comprising:
a plurality of contact pads;
an interposer comprising a plurality of liquid metal interconnects, wherein individual liquid metal interconnects of the plurality of liquid metal interconnects are adjacent an contact pad of the plurality of contact pads; and
a cap layer that seals the plurality of liquid metal interconnects,
wherein individual nails of the plurality of nails pierce the cap layer and are electrically coupled to one of the plurality of liquid metal interconnects.

13. A method comprising:
mating an adapter with an integrated circuit component, wherein the adapter comprises a plurality of nails and a plurality of pads, wherein individual pads of the plurality of pads are electrically coupled to one of the plurality of nails, wherein the integrated circuit component comprises a plurality of liquid metal interconnects and a cap layer that seals the plurality of liquid metal interconnects, wherein mating the adapter to the integrated circuit component comprises piercing the cap layer with individual nails of the plurality of nails;
mating the adapter and the integrated circuit component with a testing interface unit; and
performing one or more tests on the integrated circuit component by the testing interface unit.

14. The method of claim 13, wherein mating the adapter and the integrated circuit component with the testing interface unit comprises mating the adapter with a land grid array socket of the testing interface unit.

15. The method of claim 14, further comprising, without removing the adapter from the integrated circuit component:
removing the adapter and the integrated circuit component from the testing interface unit;
mating the adapter and the integrated circuit component with a second testing interface unit different from the testing interface unit; and
performing one or more tests on the integrated circuit component by the second testing interface unit.

16. The method of claim 13, wherein individual liquid metal interconnects of the plurality of liquid metal interconnects comprise gallium.

17. The method of claim 13, wherein individual liquid metal interconnects of the plurality of liquid metal interconnects comprise gallium and indium.

18. The method of claim 13, wherein individual liquid metal interconnects of the plurality of liquid metal interconnects comprise a low-temperature solder.

19. The method of claim 13, wherein the plurality of liquid metal interconnects comprises at least 1,000 liquid metal interconnects.

20. The method of claim 13, wherein the integrated circuit component is a processor.
